(19) United States
(12) Patent Application Publication
(10) Pub. No.: US 2025/0089514 A1
(43) Pub. Date: Mar. 13, 2025

(54) DISPLAY ELEMENT AND DISPLAY DEVICE

(71) Applicant: CANON KABUSHIKI KAISHA, Tokyo (JP)

(72) Inventors: YOSHIHIRO OHASHI, Tokyo (JP); YUTAKA YOSHIMASA, Kanagawa (JP)

(21) Appl. No.: 18/953,553

(22) Filed: Nov. 20, 2024

(30) Foreign Application Priority Data
May 30, 2022 (JP) 2022-087838

(51) Int. Cl. H10K 59/38; H10K 59/80; H10K 102/00

(52) U.S. Cl. CPC H10K 59/38; H10K 59/878; H10K 2102/331

(57) ABSTRACT

A display element includes a light-emitting-layer array and a conversion-layer array. The conversion-layer array includes a plurality of first conversion layers including a first coupling portion optically coupled to a portion of the plurality of light-emitting layers, a first extraction portion, and a first reflection portion. The first extraction portion and the first reflection portion face each other to alternately reflect the light of a first wavelength received through the first coupling portion and guide the light of the first wavelength in a direction away from the first coupling portion.

### CROSS-REFERENCE TO RELATED APPLICATIONS

This application is a Continuation of International Patent Application No. PCT/JP2023/018678, filed May 19, 2023, which claims the benefit of Japanese Patent Application No. 2022-087838, filed May 30, 2022, both of which are hereby incorporated by reference herein in their entirety.

### TECHNICAL FIELD

The present invention relates to a display element and a display device.

### BACKGROUND ART

In display elements and display devices for displaying images, a known technology for achieving high color purity and high light emission efficiency uses a light-emitting layer including quantum dots. When the light-emitting layer uses primary light as excitation light, the light-emitting layer performs wavelength conversion. Therefore, the light-emitting layer may also be referred to as a color conversion layer.

PTL 1 describes a high-resolution display device with reduced manufacturing costs and improved macroscopic light utilization efficiency achieved by forming a monolithic structure including an inorganic micro LED array that emits blue light and a color-conversion-layer array corresponding to subpixels for RGB colors. According to PTL 1, the device has a back optical arrangement in which blue light serving as excitation light is incident on the color-conversion-layer array corresponding to the subpixels for RGB colors from the back, and in which color-converted light is emitted forward from the color-conversion-layer array. According to the display device described in PTL 1, the back optical system ensures sufficient optical coupling areas between light-emitting elements and the color conversion layers and sufficient macroscopic light utilization efficiency, which is the efficiency of light propagation from the light-emitting elements to the wavelength conversion layers. PTL 1 describes a structure in which the color conversion layers contain quantum dots and a light-scattering material. The color conversion layers may also be referred to as wavelength conversion layers.

### CITATION LIST

### Patent Literature

PTL 1 Japanese Patent Laid-Open No. 2020-86461

In the pixel structure of the back optical system described in PTL 1, the optical density of quantum dots present in the wavelength conversion layers in a layer thickness direction is set to a predetermined value or more to ensure that a sufficient amount of wavelength converted light is emitted. In the pixel structure of the back optical system, primary light (excitation light) and secondary light (wavelength converted light) travel along optical paths in the same direction. In addition, the pixel structure of the back optical system has an overlapping arrangement in which first windows, which are coupling regions for guiding primary light to the wavelength conversion layers, and second windows, which correspond to light emitting surfaces through which the wavelength conversion layers emit light toward a viewer, include portions that overlap when viewed in a layer thickness direction of the conversion layer. In other words, in the pixel structure of the back optical system described in PTL 1, the primary light (excitation light) and the secondary light (wavelength converted light) are arranged coaxially.

In the pixel structure of the back optical system described in PTL 1, the concentration of the quantum dots, the absorption coefficient, or the thickness of the wavelength conversion layers, for example, may be adjusted to increase the optical density of the quantum dots, thereby increasing the light emission intensity per unit depth along the penetration depth of the primary light. According to the Beer-Lambert law, the absorption per unit depth of at least one of the primary light and the secondary light also increases, and due to the antagonism between the effect of light emission and the effect of light absorption, the increase in the macroscopic light utilization efficiency relative to the increase in the optical density of the quantum dots reaches a plateau. Thus, the pixel structure of the back optical system used in PTL 1 has limitations in improving the macroscopic light utilization efficiency through adjustments of the optical density.

When the optical density of the quantum dots in the wavelength conversion layers is reduced, although the absorption of the primary light and the secondary light per unit depth decreases, the color purity of the emitted light is reduced because the primary light reaches the light emitting surface of the color conversion layer. Although the reduction in the color purity may be alleviated by placing an optical filter on the light emission side of the wavelength conversion layers, the macroscopic light utilization efficiency of the light emitted after the color conversion is limited by the optical filter.

Thus, the method of adjusting the optical density in the layer thickness direction of the wavelength conversion layers results in at least one of the mutually conflicting issues of the limited brightness and the reduced color purity and does not lead to a fundamental improvement of the macroscopic light utilization efficiency of the wavelength conversion layers, and it is desirable to make improvements regarding this issue.

### SUMMARY OF INVENTION

The present invention has been made in light of the above-described problem, and its object is to provide a display element and a display device with which the macroscopic light utilization efficiency of the wavelength conversion layers and the color purity are both increased.

A display element according to an embodiment of the present invention includes a light-emitting-layer array and a conversion-layer array. The light-emitting-layer array includes a plurality of light-emitting layers that are arranged in two dimensions and that emit light of a first wavelength. The conversion-layer array includes a plurality of first conversion layers including a first coupling portion, a first extraction portion, and a first reflection portion. The first coupling portion is optically coupled to a portion of the plurality of light-emitting layers. The first extraction portion and the first reflection portion face each other to alternately reflect the light of the first wavelength received through the first coupling portion and guide the light of the first wavelength in a direction away from the first coupling portion. The plurality of first conversion layers emits, through the first extraction portion, light of a second wavelength obtained as a result of wavelength conversion of the light of the first wavelength.

Further features of the present invention will become apparent from the following description of exemplary embodiments with reference to the attached drawings.

### BRIEF DESCRIPTION OF DRAWINGS

FIG. 1A is a sectional view of a pixel of a green display element according to a first embodiment.

FIG. 1B is a partially removed plan view of the pixel of the green display element according to the first embodiment.

FIG. 1C is a plan view of an array-shaped display element according to the first embodiment.

FIG. 1D is a sectional view of a pixel of a red display element according to the first embodiment.

FIG. 1E is a sectional view of a pixel of a blue display element according to the first embodiment.

FIG. 2A illustrates the cross-sectional structure of a display element according to the first embodiment.

FIG. 2B illustrates the cross-sectional structure of a display element according to the related art.

FIG. 2C illustrates the internal structure of a wavelength conversion layer according to the first embodiment.

FIG. 2D illustrates the internal structure of a wavelength conversion layer according to the related art.

FIG. 3A is a sectional view illustrating the pixel structure according to the related art.

FIG. 3B is a sectional view illustrating the pixel structure according to the related art.

FIG. 4 illustrates the waveguide characteristics of a conversion layer applicable to each embodiment.

FIG. 5A is a sectional view of a pixel of a display element according to a second embodiment.

FIG. 5B is a sectional view of a pixel of a display element according to a third embodiment.

FIG. 5C is a sectional view of a pixel of a display element according to a fourth embodiment.

FIG. 5D is a sectional view of a pixel of a display element according to a fifth embodiment.

FIG. 5E is a sectional view of a pixel of a display element according to a sixth embodiment.

FIG. 5F is a sectional view of a pixel of a display element according to a seventh embodiment.

FIG. 6A is a sectional view of a pixel of a display element according to an eighth embodiment.

FIG. 6B illustrates the brightness distribution profile of the display element according to the eighth embodiment.

FIG. 6C is a sectional view of a pixel of a display element according to a ninth embodiment.

FIG. 6D illustrates the brightness distribution profile of the display element according to the ninth embodiment.

FIG. 6E is a sectional view of a pixel of a display element according to a tenth embodiment.

FIG. 6F illustrates the brightness distribution profile of the display element according to the tenth embodiment.

FIG. 6G is a sectional view of a pixel of a display element according to an eleventh embodiment.

FIG. 6H is a plan view of the pixel of the display element according to the eleventh embodiment.

FIG. 6I is a sectional view of a pixel of a display element according to a twelfth embodiment.

FIG. 6J is a plan view of the pixel of the display element according to the twelfth embodiment.

FIG. 7A is a plan view of a pixel of a display element according to a thirteenth embodiment.

FIG. 7B is a sectional view of the pixel of the display element according to the thirteenth embodiment.

FIG. 7C is an array plan view of the display element according to the thirteenth embodiment.

FIG. 8A is a plan view of a pixel of a display element according to a fourteenth embodiment.

FIG. 8B is a sectional view of the pixel of the display element according to the fourteenth embodiment.

FIG. 8C is an array plan view of the display element according to the fourteenth embodiment.

### DESCRIPTION OF EMBODIMENTS

Display elements according to embodiments of the present invention will now be described in detail. The present invention is not limited to the embodiments.

### First Embodiment

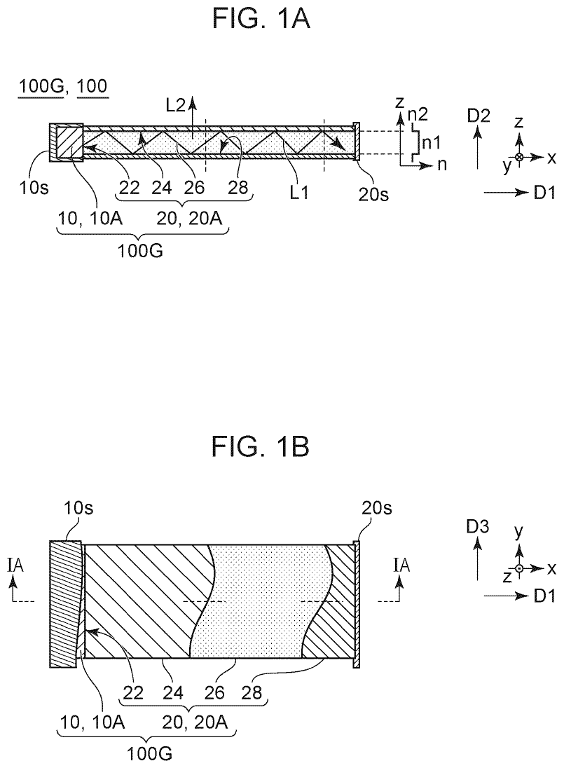

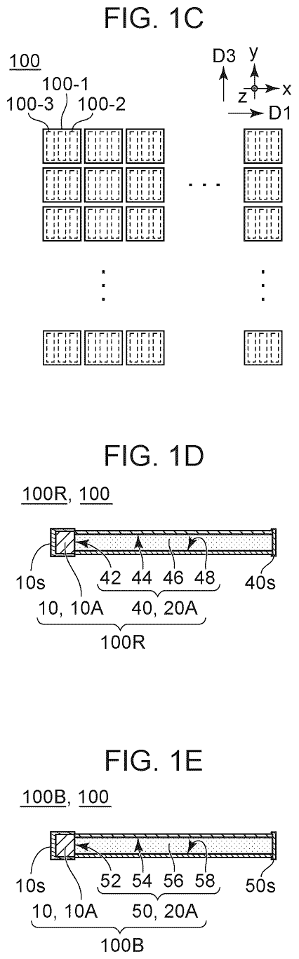

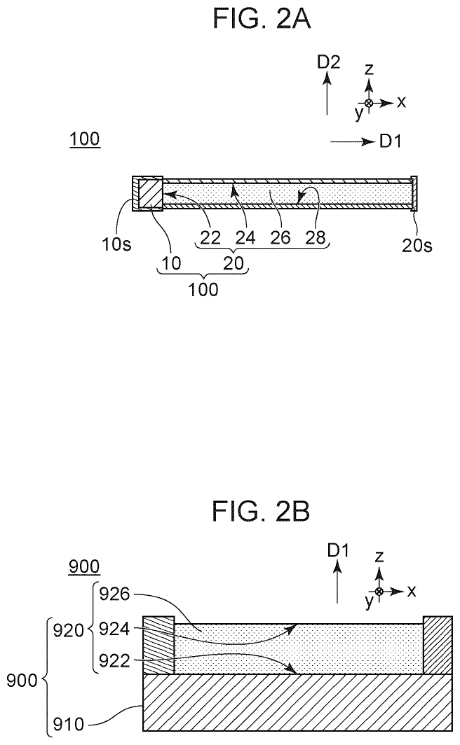

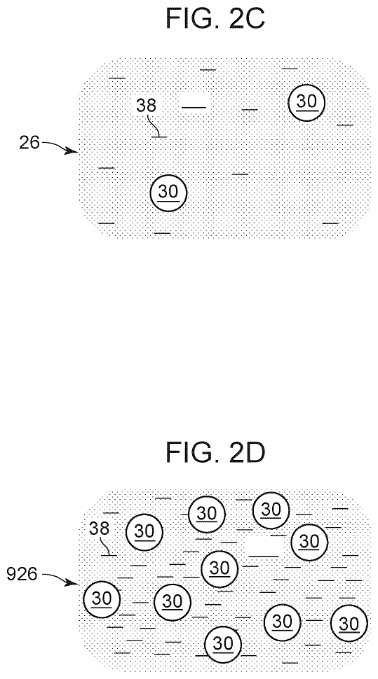

A display element 100 according to a first embodiment will be described with reference to FIGS. 1A to 1E, FIG. 2A, and FIG. 2C.

FIG. 1A is a sectional view illustrating the pixel structure of a green display element 100G according to the present embodiment, and FIG. 1B is a partially removed plan view illustrating the pixel structure of the green display element 100G. FIG. 1C is a plan view of an array-shaped display element 100 having a matrix pattern according to the present embodiment. FIG. 1D is a sectional view illustrating the pixel structure of a red display element 100R according to the present embodiment. FIG. 1E is a sectional view illustrating the pixel structure of a blue display element 100B according to the present embodiment. The two-dimensional arrangement of the display elements may be a delta arrangement (Δ arrangement) depending on the target display performance, and may be changed as appropriate.

In this specification, green, red, and blue are regarded as having local maxima at least in wavelength bands of 515 nm or more and 545 nm or less, 615 nm or more and 645 nm or less, and 445 nm or more and 475 nm or less, respectively. More preferably, green, red, and blue have local maxima at wavelengths in the regions of 528 nm or more and 532 nm or less, 628 nm or more and 632 nm or less, and 458 nm or more and 462 nm or less, respectively. In the embodiments described below, each of green light, red light, and blue light, which are secondary light having second to fourth wavelengths, preferably has a bandwidth (full width at half maximum (FWEM)) whose upper limit is 10 nm.

### First Display Element Array

The green display element 100G that displays green will be described with reference to FIGS. 1A to 1C, 2A, and 2C. As illustrated in FIG. 1C, the green display element 100G is a two-dimensional array of units 100-1 arranged along a first direction D1 and a third direction D3 in a matrix pattern. Alternatively, the green display element 100G may be a two-dimensional array of units 100-2 or units 100-3, or be disposed in a portion or the entirety of a display element array of the units 100-1, 100-2, and 100-3. FIG. 1A is a sectional view of the structure of the display element 100 taken along plane IA-IA in a plan view of display element 100 illustrated in FIG. 1B. In FIG. 1B, to facilitate understanding of elements stacked in layers, a light-shielding portion 10s, a first extraction portion 24, and a first conversion portion 26 are partially removed.

### Light-Emitting-Layer Array

As illustrated in FIGS. 1A and 1B, the green display element 100G according to the present embodiment includes a light-emitting-layer array 10A including a plurality of light-emitting layers 10 that are arranged in two dimensions and each of which emits light L1 having a first wavelength. The light-emitting-layer array 10A may be, for example, a self-emitting element, such as an inorganic semiconductor light-emitting diode (LED), an organic light emitting diode (OLED), or a semiconductor laser element. Light-emitting elements that constitute the first light-emitting layers 10 may be micro light-emitting diodes (LEDs) or micro organic light-emitting diodes (OLEDs) having a microcavity structure.

Since the light-emitting elements are light sources having directivity, the light L1 of the first wavelength can be guided into a first conversion layer 20 in waveguide modes.

To guide the light L1 of the first wavelength to a first coupling portion 22 included in a first conversion layer 20 described below and prevent leakage of light to regions around each light-emitting layer 10, the light-emitting-layer array 10A includes the light-shielding portion 10s that shields each light-emitting layer 10 from light in regions excluding the region in which the light-emitting layer 10 is coupled to the first coupling portion 22.

### Conversion-Layer Array

The green display element 100G also includes a conversion-layer array 20A including a plurality of first conversion layers 20 that convert the light L1 of the first wavelength guided from the light-emitting-layer array 10A into light L2 of a second wavelength and changes the propagation direction of the light L1 of the first wavelength and the light L2 of the second wavelength. As illustrated in FIGS. 1A and 1B, the light propagation direction to be changed is the direction in which light is propagated through each first conversion layer 20, and may be referred to also as a light transmission direction or a light utilization direction.

As illustrated in FIGS. 1A and 1B, each first conversion layer 20 includes the first coupling portion 22 that is optically coupled to a portion of the light-emitting layers 10. The first conversion layer 20 has a waveguide-shaped optical structure in which the light L1 of the first wavelength (λ1) received through the first coupling portion 22 is reflected in alternate directions and guided in the direction D1 away from the first coupling portion 22 while undergoing multiple reflection. The waveguide-shaped optical structure includes the first extraction portion 24 and a first reflection portion 28 that face each other.

### Conversion Portion

As illustrated in FIGS. 1A and 2C, each first conversion layer 20 includes a first conversion portion 26 containing a plurality of photoresponsive nanoparticles 30 that serve as quantum dots. The first conversion layer 20 emits the light L2 of the second wavelength (λ2) obtained by shifting the light L1 of the first wavelength (λ1) toward the long-wavelength side. In other words, the second wavelength λ2 is longer than the first wavelength λ1.

Each first conversion layer 20 may be regarded as a light-emitting layer that reduces a bandwidth Δλ1 around the center wavelength of the light L1 of the first wavelength to a bandwidth Δλ2 to generate the secondary light L2 having a higher color purity than the primary light L1. The first conversion layer 20 may include a band-pass filter (color filter) instead of the quantum dots to perform the wavelength conversion.

First conversion layers 20-1 and second conversion layers 20-2 convert the light L1 of the first wavelength into light having a wavelength different from the wavelength of the light L1 of the first wavelength. The conversion-layer array 20A includes the first conversion layers 20-1 that convert the light L1 of the first wavelength into the light L2 of the second wavelength and the second conversion layers 20-2 that convert the light L1 of the first wavelength into light L3 of a third wavelength. The light L2 of the second wavelength is green, and the light L3 of the third wavelength is red light. In the present embodiment, the thicknesses of the first conversion layers and the second conversion layers 20-2 are preferably 4 μm or more and 20 μm or less, and more preferably 6 μm or more and 10 μm or less.

The conversion layers may contain fluorescent particles dispersed in a resin. The fluorescent particles may be made of either an inorganic material or an organic material, but quantum dots are preferably used. This is because quantum dots emit light with an emission spectrum having a narrow full width at half maximum and a high color purity.

The inorganic particles used as quantum dots may be referred to as nanoparticles because of their sizes. The material of the quantum dots may be, for example, semiconductor crystals, and may be nanoparticles of a group IV semiconductor, a group III-V or group II-VI compound semiconductor, or a compound semiconductor of a combination of three or more of group II, group III, group IV, group V, and group VI elements. Examples of materials that emit light in a wavelength band for a display element include CsS, CdSe, CdZnSe, CdSeTe, ZnSe, ZnTeSe, ZnTeS, InP, CuInS₂, AgInS₂, and Pb-based perovskite. These materials may be used to form cores of quantum dots, and the quantum dot materials may be covered with a coating compound to form a core shell structure. In this case, the shells are provided with ligands.

The quantum dots preferably have an average particle size of 2 nm or more and 15 nm or less. When the particle size of the quantum dots is reduced to or below the Bohr radius of excitons in the quantum dots, the band gap of quantum dots changes due to the quantum size effect. For example, the Bohr radius for InP, which is a group III-V semiconductor, is said to be about 10 nm to 14 nm. Therefore, when the average particle size of the quantum dots is 15 nm or less, the band gap can be controlled by the quantum size effect. When the average particle size of the quantum dots is 2 nm or more, the crystal growth of the quantum dots can be easily controlled during synthesis of the quantum dots.

The quantum dots have ligands on the surfaces thereof. When a first quantum dot and a second quantum dot are provided, the ligands may have a cross-linking structure that cross-links the first and second quantum dots. Cross-linking means coupling of one molecule with the first quantum dot and the second quantum dot. When the quantum dots are cross-linked by organic ligands, the distance between the quantum dots can be controlled based on the molecular length of the organic ligands. Specifically, the cross-linking structure may be a hydroxyl group, a thiol group, or a carboxyl group. At least one or more organic molecules are preferably provided between the quantum dots. When a large number of organic ligands are provided, since both ends of each organic molecule are strongly coupled to the surfaces of the quantum dots, the heat resistance and the resistance to the environment are improved, and the stability of the light emitting characteristics increases.

The fluorescent particles used in the first conversion layers and the second conversion layers of the present embodiment are preferably quantum dots having a full width at half maximum of less than 50 nm. For example, the quantum dots may be generally available quantum dots, such as InP/ZnS quantum dots available from Sigma-Aldrich as product numbers 776769, 776750, 776793, 776777, and 776785. Product number 776750 is preferable for the first conversion layers, and product number 776777 is preferable for the second conversion layers 20-2. As perovskite quantum dots, product numbers 905062, 900746, 900747, and 900748 may be used. Product number 905062 or 900746 is preferable for the first conversion layers, and product number 900748 is preferable for the second conversion layers 20-2.

In the first to third conversion portions 26 according to the present embodiment, the material that serves as the polymer matrix may be a monofunctional monomer or a bifunctional monomer, and examples of the material include acrylic resins, polyester resins, polyurethane resins, and polyamide resins. These materials may be mixed with photoresponsive nanoparticles to achieve the viscosity and surface tension suitable for photolithography or inkjet film formation (inkjet printing). When the concentration of the monomer is 85 to 98 wt %, the concentration of the photopolymerization initiator is 2 to 5 wt %. Titanium oxide is not contained. A resin portion 17 contains a light-scattering material, such as titanium oxide, that scatters blue light (L3), but the concentration of the material is preferably 5 wt % or less so that multiple scattering does not occur.

### Extraction Portion

The first extraction portion 24 is structured to have a spectral reflectance that is higher for the light L1 of the first wavelength that propagates in the first direction D1 away from the first coupling portion 22 than for the light L2 of the second wavelength that is generated by wavelength conversion in the first conversion layer 20 and that propagates radially. When the first extraction portion 24 having such a structure is used together with the first reflection portion 28 described below, the propagation performance of the light L1 of the first wavelength, which serves as a source of the light L2 of the second wavelength, in the layer and the generation region for the light L2 of the second wavelength are ensured.

The first extraction portion 24 is structured to have a spectral transmittance that is higher for the light L2 of the second wavelength than for the light L1 of the first wavelength. Accordingly, of the light L1 of the first wavelength and the light L2 of the second wavelength mixed in the first conversion layer 20, the first extraction portion 24 limits the emission of the light L1 of the first wavelength from the display surface while allowing the emission of the light L2 of the second wavelength from the display surface. Thus, a high color purity is achieved.

The spectral reflection characteristics or spectral transmission characteristics of the first extraction portion 24 are obtained based on the difference in refractive index n between optical members (not illustrated) in contact with both surfaces in the layer thickness direction of the first conversion portion 26 (z direction). As illustrated in FIG. 1A, in the display element 100 according to the present embodiment, a refractive index n1 of the first conversion portion 26 is higher than a refractive index n2 of an optical structure on an interface side of the first extraction portion 24.

The first extraction portion 24 may be a dielectric multilayer film. Alternatively, the first extraction portion 24 may have a core-cladding structure that utilizes the difference in refractive index as described above.

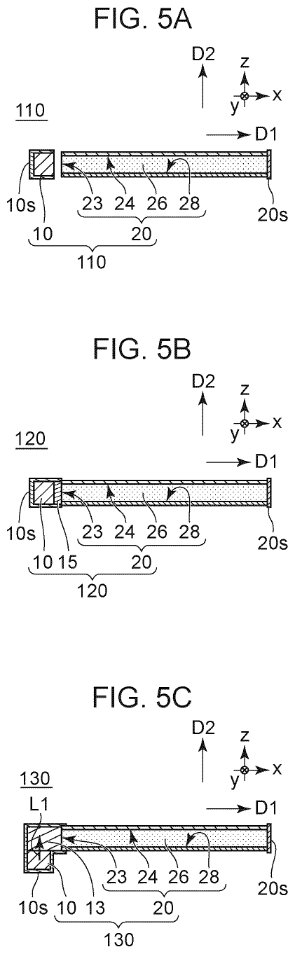

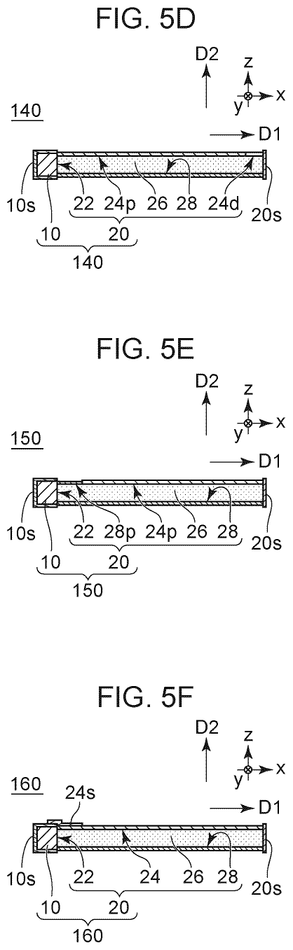

The waveguide-shaped optical structure of the first extraction portion 24 and the first conversion portion 26 will be described in detail below with reference to FIGS. 5A to 5F illustrating a display element 200 according to a thirteenth embodiment.

### Reflection Portion

The first reflection portion 28 is structured to have a higher spectral reflectance for the light L2 of the second wavelength than the first extraction portion 24. When the first reflection portion 28 having such a structure is used together with the above-described first extraction portion 24, the propagation performance of the light L1 of the first wavelength, which serves as a source of the light L2 of the second wavelength, in the layer and the generation region for the light L2 of the second wavelength are ensured.

The spectral reflection characteristics of the first reflection portion 28 are obtained based on the difference in refractive index n between optical members (not illustrated) in contact with both surfaces in the layer thickness direction of the first conversion portion 26 (z direction). As illustrated in FIG. 1A, in the display element 100 according to the present embodiment, the refractive index n1 of the first conversion portion 26 is higher than the refractive index n2 of an optical structure (not illustrated) on an interface side of the first reflection portion 28.

The first reflection portion 28 is a metal reflective member having a low wavelength dependence utilizing plasmon reflection. Alternatively, the first reflection portion 28 may be a dielectric multilayer film or have a core-cladding structure that utilizes the difference in refractive index similarly to the first extraction portion 24.

The first conversion layer 20 includes a terminal-end light-shielding portion 20s at a terminal end thereof that is opposite to the end at which the first coupling portion 22 is provided in the first direction D1.

### Optical Members

Each optical member forms an interface between the optical member and the conversion portion 26 to constitute the extraction portion 24 or the reflection portion 28. The optical member that constitutes the extraction portion 24 is made of a light-transmitting material that allows transmission of the secondary light passing through the extraction portion 24. The material may be, for example, an organic resin or an inorganic glass material. The optical member may be made of, for example, a transparent resin having a transmittance of 85% or more, more preferably 90% or more, for blue light, green light, and red light. The resin used as the optical member may have a refractive index of 1.45 or more and 1.5 or less.

The refractive index of the optical members is set so that the conversion layer 20 serves as a waveguide. The refractive index (n₁) of the conversion layer varies depending on the type and concentration of the quantum dots. When the concentration is 0.01 to 5 wt %, n₁ is roughly in the range of 1.45 to 1.50. The refractive index (n₂) of the optical members is preferably set so that a difference of refractive index ratio Δ calculated as Δ=(n₁−n₂)/2n₁ is 0.3% to 2.0%. For example, when the refractive index n₁ of the conversion layer is 1.50, n₂=1.490 when Δ=0.35%, and n₂=1.455 when Δ=1.5%.

### Second Display Element Array

A red display element 100R that displays red will be described with reference to FIGS. 1C and 1D. As illustrated in FIG. 1C, the red display element 100R is a two-dimensional array of units 100-2 arranged along the first direction D1 and the third direction D3 in a matrix pattern. Alternatively, the red display element 100R may be a two-dimensional array of units 100-1 or units 100-3, or be disposed in a portion or the entirety of a display element array of the units 100-1, 100-2, and 100-3.

FIG. 1D illustrates the cross-sectional structure of the red display element 100R according to the present embodiment as a second display element array 100A.

Similarly to the green display element 100G, the red display element 100R according to the present embodiment includes a light-emitting-layer array 10A including a plurality of light-emitting layers 10 and a conversion-layer array 20A including a plurality of second conversion layers 40. Similarly to each first conversion layer 20, each second conversion layer 40 may perform wavelength conversion on the light L1 of the first wavelength (primary light) including blue or ultraviolet color toward the long-wavelength side and emit red secondary light from a second extraction portion 44 as the light L3 of the third wavelength. Similarly to each first conversion layer 20, each second conversion layer 40 may reduce the bandwidth of the light L1 of the first wavelength (primary light) including blue or ultraviolet color to a bandwidth smaller than that of the light L1 of the first wavelength to generate the light L3 of the third wavelength, which is the red secondary light, and emit the light L3 of the second wavelength from the second extraction portion 44.

Similarly to each first conversion layer 20, each second conversion layer 40 includes a second coupling portion 42, the second extraction portion 44, a second reflection portion 48, and a second conversion portion 46. The second conversion layer 40 having such a structure performs wavelength conversion on the light L1 of the first wavelength received through the second coupling portion 42 to generate the light L3 of the third wavelength, and emits the light L3 of the third wavelength through the second extraction portion 44 serving as a display surface.

Specifically, the conversion-layer array 20A includes the second conversion layers 40 including the second coupling portions 42 optically coupled to the light-emitting layers 10 in regions other than the regions in which the light-emitting-layer array 10A is optically coupled to the first conversion layers 20. In addition, each second conversion layer 40 includes the second extraction portion and the second reflection portion facing each other to alternately reflect the light L1 of the first wavelength received through the second coupling portion 42 and guide the light L1 of the first wavelength in the direction D1 away from the second coupling portion 42. Each second conversion layer 40 performs wavelength conversion on the light L1 of the first wavelength to obtain the light L3 of the third wavelength and emit the light L3 of the third wavelength through the second extraction portion 44.

Similarly to each first conversion layer 20, each second conversion layer 40 contains second photoresponsive nanoparticles that convert the light L1 of the first wavelength into the light L3 of the third wavelength.

Similarly to the first extraction portion 24, the second extraction portion 44 is structured to have a spectral reflectance that is higher for the light L1 of the first wavelength than for the light L3 of the third wavelength. Similarly to the first extraction portion 24, the second extraction portion 44 is structured to have a spectral transmittance that is higher for the light L3 of the third wavelength than for the light L1 of the first wavelength.

Similarly to the first reflection portion 28, the second reflection portion 48 is structured to have a higher spectral reflectance for the light L3 of the third wavelength than the second extraction portion 44.

### Third Display Element Array

A blue display element 100B that displays blue will be described with reference to FIGS. 1C and 1E. As illustrated in FIG. 1C, the blue display element 100B is a two-dimensional array of units 100-3 arranged along the first direction D1 and the third direction D3 in a matrix pattern. Alternatively, the blue display element 100B may be a two-dimensional array of units 100-1 or units 100-2, or be disposed in a portion or the entirety of a display element array of the units 100-1, 100-2, and 100-3.

FIG. 1E illustrates the cross-sectional structure of the blue display element 100B according to the present embodiment as a third display element array 100B.

Similarly to the green display element 100G and the red display 100R, the blue display element 100B according to the present embodiment includes a light-emitting-layer array 10A including a plurality of light-emitting layers 10 and a conversion-layer array 20A including a plurality of third conversion layers 50. Similarly to the green display element 100G, each third conversion layer 50 may receive the light L1 of the first wavelength (primary light) including blue or ultraviolet color, generate light L4 of a fourth wavelength that serves as blue secondary light with a bandwidth smaller than that of the light L1 of the first wavelength, and emit the light L4 of the fourth wavelength from a third extraction portion 54. Thus, the third conversion layer 50 may change the propagation direction in the optical propagation path from a third coupling portion 52 to the third extraction portion 54 without performing wavelength conversion on the light L1 of the first wavelength.

Similarly to each first conversion layer 20, each third conversion layer 50 includes the third coupling portion 52, the third extraction portion 54, a third reflection portion 58, and a third conversion portion 56. The third conversion layer 50 having such a structure performs wavelength conversion on the light L1 of the first wavelength received through the third coupling portion 52 to generate the light L4 of the fourth wavelength, and emits the light L4 of the fourth wavelength through the third extraction portion 54 serving as a display surface.

Specifically, the conversion-layer array 20A includes the third conversion layers 50 including the third coupling portions 52 optically coupled to the light-emitting layers 10 in regions other than the regions in which the light-emitting-layer array 10A is optically coupled to the first conversion layers 20. In addition, each third conversion layer 50 includes the third extraction portion and the third reflection portion facing each other to alternately reflect the light L1 of the first wavelength received through the third coupling portion 52 and guide the light L1 of the first wavelength in the direction D1 away from the third coupling portion 52. Each third conversion layer 50 performs wavelength conversion on the light L1 of the first wavelength to obtain the light L4 of the fourth wavelength and emit the light L4 of the fourth wavelength through the third extraction portion 54.

Similarly to each first conversion layer 20, each third conversion layer 50 may contain third photoresponsive nanoparticles that convert the light L1 of the first wavelength into the light L4 of the fourth wavelength, which is closer to the first wavelength than the second wavelength and the third wavelength. The fourth wavelength may be longer than the first wavelength and shorter than the second wavelength and the third wavelength.

The third extraction portion 54 is structured to have a spectral reflectance that is higher for the light L1 of the first wavelength than for the light L4 of the fourth wavelength. Similarly to the first extraction portion 24, the third extraction portion 54 is structured to have a spectral transmittance that is higher for the light L4 of the fourth wavelength than for the light L1 of the first wavelength.

Similarly to the first reflection portion 28, the third reflection portion 58 is structured to have a higher spectral reflectance for the light L4 of the fourth wavelength than the third extraction portion 54.

The first conversion portion 26, the second conversion portion 46, and the third conversion portion 56 may contain a light-scattering material, such as titanium oxide, that scatters the light L1 of the first wavelength. The concentration of the light-scattering material in the first conversion portion 26, the second conversion portion 46, and the third conversion portion 56 is preferably less than or equal to a certain concentration so that multiple scattering between elements of the light-scattering material does not occur, and may be 5 wt % or less.

### Technical Features

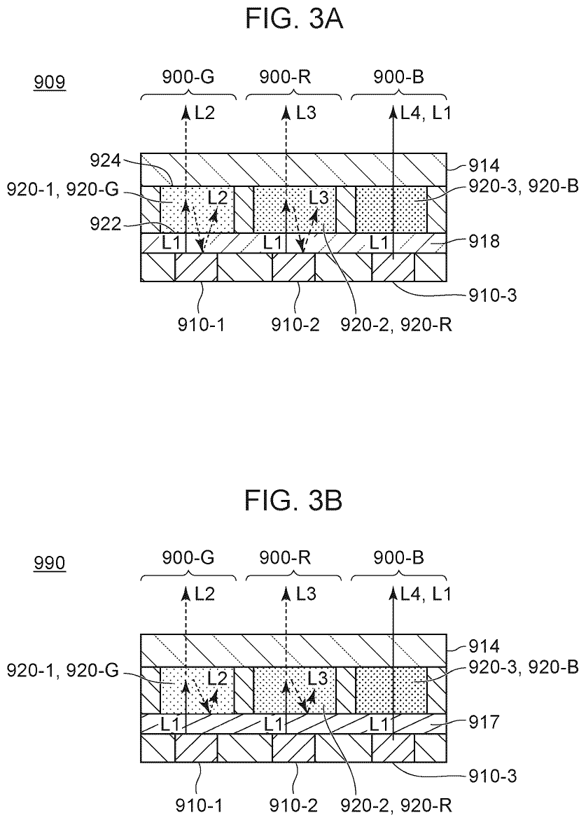

Referring to FIGS. 2A to 2D, 3A, and 3B, the display element 100 according to the present embodiment will be compared with a display element 900 according to the related art to describe the structural characteristics of the display element 100 and unique effects of the present embodiment that the structural characteristics provide.

FIG. 2A illustrates the cross-sectional structure of the display element 100 according to the first embodiment, and FIG. 2C illustrates the internal structure of the first conversion layer 20 according to the first embodiment. FIG. 2B illustrates the cross-sectional structure of the display element 900 according to the related art, and FIG. 2D illustrates the internal structure of a conversion layer 920 included in the display element 900 according to the related art. FIGS. 2C and 2D illustrate the manner in which photoresponsive nanoparticles 30 are dispersed in the first conversion portion 26 of the display element 100 and a conversion portion 926 of the display element 900, respectively.

The display element 100 and the display element 900 have differences A, B, and C described below.

The difference A is whether the propagation path of the primary light and the propagation path of the secondary light are non-coaxial or coaxial in the optical propagation path from the coupling portion to the extraction portion. In the display element 100, the optical propagation path from the first coupling portion 22 to the first extraction portion 24 has a non-coaxial arrangement in which the directions of the propagation paths of the primary light and the secondary light are different. In contrast, in the display element 900, the optical propagation path from a coupling portion 922 to an extraction portion 924 has a coaxial arrangement in which the directions of the propagation paths of the primary light and the secondary light are the same. In other words, the display element 100 is structured such that, when viewed along an axis parallel to the layer thickness direction D2 of the conversion layer 20, the first coupling portion 22 and the first extraction portion 24 do not overlap. The layer thickness direction D2 of the conversion layer 20 may also be referred to as a light extraction direction. The display element 100 may also be referred to as being structured such that, when viewed in the first light propagation direction D1 of the conversion layer 20, the first coupling portion 22 and the first extraction portion 24 do not overlap.

The difference B is whether or not a reflection portion can be disposed over the entire region at a position facing the extraction portion. In the display element 100, the optical propagation path from the first coupling portion 22 to the first extraction portion 24 has the non-coaxial arrangement. In contrast, in the display element 900, the optical propagation path from the coupling portion 922 to the extraction portion 924 has the coaxial arrangement.

The difference C is whether or not the optical density of the photoresponsive nanoparticles can be reduced so that the absorption of the primary light and the secondary light that propagate does not exceed the effect of light emission.

The above-described differences A to C will be further described.

According to the differences A and B, the display element 100 of the present embodiment can be structured such that the first coupling portion 22 and the first reflection portion 28, which are optical elements having different functions, can be arranged at appropriate positions. Therefore, according to the display element 100, light reception characteristics of the first conversion layer 20 receiving light from the light-emitting layer 10 and the reflection characteristics of the first reflection portion 28 can be set to appropriate optical characteristics without mutual restriction. In other words, the first coupling portion 22 may be set to have a high transmittance for the light L1 of the first wavelength, which is the primary light, and the first reflection portion 28 may be set to have a high reflectance for both the light L1 of the first wavelength (primary light) and the light L2 of the second wavelength (secondary light). In addition, according to the display element 100, the reflection portion 28 may be formed of a metal layer having a robust wavelength dependence, and the reflection portion 28 may be provided over the entire region behind the extraction portion 24. Accordingly, the macroscopic light utilization efficiency of light from the first conversion layer 20 can be increased.

In contrast, the display element 900 according to the related art does not have the features of differences A and B, and therefore requires both an optical coupling element for receiving the primary light from the light-emitting layer 910 and a reflection element for reflecting the secondary light generated in the conversion layer 920 at the position denoted by reference numeral 922. Therefore, in the display element 900, at least one of the transmittance and the reflectance is limited at the interface denoted by reference numeral 922, or the region denoted by the reference numeral 922 needs to be divided into sections allocated to the respective characteristics. Thus, the macroscopic light utilization efficiency of light from the conversion layer 920 is limited.

In the display element 100 according to the present embodiment, the propagation path of the light L1 of the first wavelength extends not in the layer thickness direction of the display element 900 (z direction) but in a layer surface direction (direction along an xy plane) substantially parallel to the layer surfaces, and the propagation distance is increased by approximately one order of magnitude. Therefore, the display element 100 can be structured such that the optical density of the photoresponsive nanoparticles is reduced from that in the display element 900 by approximately one order of magnitude, and has the difference C.

Accordingly, in the display element 100 of the present embodiment, the generation of the secondary light is not easily limited by the absorption of the primary light and the secondary light, and the macroscopic light utilization efficiency of the first conversion layer 20 is higher than that in the display element 900.

The display element 100 according to the present embodiment and the display element 900 according to the related art will be further compared.

The display element 900 includes the light-emitting layer 910 that emits the light L1 of the first wavelength (blue, primary light) and the conversion layer 920 that contains photoresponsive nanoparticles that receive the primary light from the light-emitting layer 910 and emit the light L2 of the second wavelength (green, secondary light). The light-emitting layer 910 and the conversion layer 920 are stacked with the coupling portion 922 interposed therebetween. The layer thickness of the conversion layer 920 is several to ten micrometers. To achieve total absorption of the light L1 of the first wavelength in the propagation path having the above-described layer thickness, the conversion layer 920 contains the photoresponsive nanoparticles 30 at a concentration of 10 to 30 wt %, as illustrated in FIG. 2D. To increase the utilization efficiency of the light L1 of the first wavelength and reduce the leakage of the light to the extraction surface 924, the conversion layer 920 contains 10 to 30 wt % of titanium oxide, for example, as a light-scattering material 38. In the conversion layer 920, the light-scattering material 38 scatters the light L1 of the first wavelength multiple times to increase the chance of absorption of the light L1 of the first wavelength by the photoresponsive nanoparticles 30 per unit thickness in the layer thickness direction (depth direction, z direction), thereby increasing the wavelength conversion efficiency.

The photoresponsive nanoparticles 30 (quantum dots) have a small Stokes shift, and the emission and excitation bands partially overlap. Accordingly, self-absorption easily occurs. Therefore, when the optical density of the photoresponsive nanoparticles 30 is high, the light emission efficiency is easily reduced due to self-absorption. In addition, since the photoresponsive nanoparticles 30 are at close distances from each other, the light emission efficiency is easily reduced due to fluorescence resonance energy transfer (FRET). In addition, since the light-scattering material 38 also scatters the wavelength converted light, which is the secondary light, the effective optical distance is increased, causing a reduction in the light extraction efficiency.

In particular, among the secondary light propagated in the direction opposite to the light extraction direction D1 and emitted out of the conversion layer 920, light that is re-incident on the conversion layer 920 is likely to have a lower light extraction efficiency due to attenuation by self-absorption by the photoresponsive nanoparticles 30 and the shielding effect of the light-scattering material 38.

The RGB pixel arrangement according to the related art will be described with reference to FIGS. 3A and 3B.

A display element 909 illustrated in FIG. 3A includes an optical member 918 provided on the back side (side adjacent to the light-emitting layer 910) of conversion layers 920-1 to 920-3 to form the coupling portion 922. The coupling portion 922 has a function of scattering the primary light L1 forward (toward an optical member 914) by using the difference in refractive index between the optical member 918 and the conversion layers 920-1 to 920-3. To balance the efficiency in receiving the primary light L1 from the light-emitting layers 910-1 to 910-3 and the forward reflection characteristics, at least the reflection characteristics or the transmission characteristics of the coupling portion 922 are limited as described above.

A display element 990 illustrated in FIG. 3B includes a dielectric multilayer film 917 provided on the back side (side adjacent to the light-emitting layer 910) of the conversion layers 920-1 to 920-3 to form the coupling portion 922. Accordingly, among the wavelength conversion light, the secondary light L2 and the secondary light L3 propagated toward and returned from the light-emitting layers 910-1 to 910-3 are used.

As described above, in each of the display elements 909 and 990, the macroscopic light utilization efficiency is likely to be reduced due to the loss caused by the conversion layers 920-1 to 920-3 and the reduction in the utilization efficiency of the secondary light (wavelength converted light) emitted rearward. The loss caused by the conversion layers 920-1 to 920-3 includes the self-absorption of the quantum dots and the shielding effect of the light-scattering material.

To balance the efficiency in receiving the primary light L1 from the light-emitting layers 910-1 to 910-3 and the forward reflection characteristics, at least the reflection characteristics or the transmission characteristics of the coupling portion 922 are limited as described above.

In contrast, in the display element 100 according to the present embodiment, the conversion layer 20 functions as a waveguide for the light L1 of the first wavelength (primary light) that propagates in the first direction D1. The conversion layer 20 having the waveguide function performs the wavelength conversion on the light L1 of the first wavelength (blue light) to obtain the secondary light while guiding the light L1 of the first wavelength along the layer surface direction of the conversion layer 20 by total reflection. According to the structure of the present embodiment, the light L1 of the first wavelength, specifically the blue light that serves as the primary light, is propagated over a longer optical path length than in the structure of the related art while undergoing the wavelength conversion. For example, in 100 μm×300 μm subpixels, the optical path length may be 100 μm in the short direction or 300 μm in the long direction. According to the Beer-Lambert law, as the absorption optical path length increases, the concentration of quantum dots (concentration of photoresponsive nanoparticles) in the conversion layer 20 can be reduced.

Compared to the display elements 900, 909, and 990 according to the related art, in the display element 100 according to the embodiment, the optical path length for the light L1 of the first wavelength can be increased by approximately one order of magnitude. Therefore, the concentration of the quantum dots can be reduced by one order of magnitude. When the concentration of the quantum dots is low, the reduction in the light emission efficiency due to self-absorption and FRET can be suppressed, so that the light emission efficiency can be increased. Thus, in the structure of the present embodiment, the concentration of the quantum dots may be set to 0.01 to 5 wt %. The concentration of the quantum dots is determined based on the pixel size corresponding to the optical propagation path length of the primary light as well as the required display performance, the driving conditions of the primary light, and other factors. In the structure according to the present embodiment, the reflection portion 28 does not need to be a wavelength selective mirror, and a metal mirror made of, for example, Al or Ag may be used. Alternatively, a wavelength selective mirror composed of a dielectric multilayer film may be used.

### Waveguide Modes and Emission Modes

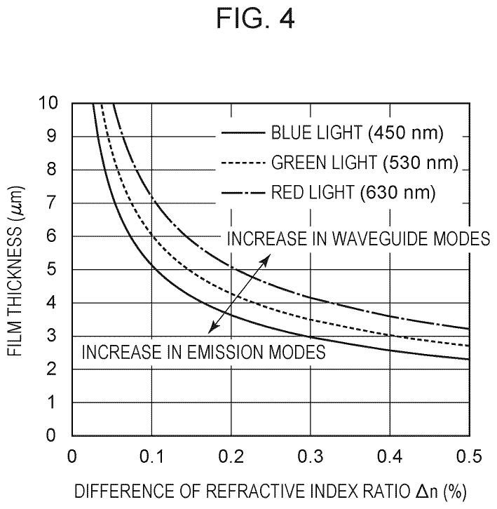

The operation modes of the waveguide-shaped first to third conversion layers 20-1 to 20-3 will be described with reference to FIGS. 1A to 1E and FIG. 4.

In the structure of the present invention, as illustrated in FIG. 1A, the refractive index (n2) of the first extraction portion 24, which is the optical member defining the interface, is lower than the refractive index (n1) of the first conversion layer 20, and the first conversion layer 20 serves as a waveguide. As a result, the light L1 of the first wavelength (primary light, blue light) propagates and is guided while being repeatedly totally reflected within the first conversion layer 20. FIG. 1A illustrates only a portion of the light L2 of the second wavelength, which is the wavelength converted light generated in the first conversion layer 20, and paths of the light L2 of the second wavelength reflected by the first reflection portion 28 are omitted. In practice, the light L2 of the second wavelength is generated in the propagation path of the light L1 of the first wavelength composed of a plurality of optical paths, and is also generated around the propagation path due to the light-scattering material. The secondary light generated in the first conversion layer 20 is emitted forward from the first conversion layer 20 after being scattered by the light-scattering material and reflected by the reflection portion 28, or after directly reaching the extraction portion 24 from the light emitting point (wavelength conversion point).

When a high-refractive-index layer (core) is disposed between low-refractive-index layers (cladding) to form a sandwich structure, total reflection occurs when the incident angle of the light that propagates through the core layer on the cladding layers exceeds a critical angle. The reflection at the core-cladding interface is repeated so that the structure serves as a waveguide. In general, among all radiation modes that are isotropically radiated from the core layer, modes of light that is repeatedly totally reflected within the core layer are referred to as waveguide modes, and modes of light that is extracted from the core layer are referred to as emission modes.

The waveguide modes are used for the light L1 of the first wavelength (primary light, blue, violet). For the light L2 of the second wavelength (green) and the light L3 of the third wavelength (red), to enable extraction of the light, settings are made so that the components of the waveguide modes are less than those of the emission modes. More preferably, for the light L2 of the second wavelength and the light L3 of the third wavelength, the emission modes are dominant over the waveguide modes.

In this specification, the waveguide modes and the emission modes are discussed using a waveguide parameter V used for optical waveguides.

$$V < 2.405 \qquad ( Expression 1 )$$

$$V = \frac{π d}{2 {λ [ n {1}^{2} - n {2}^{2} ]}^{1 / 2}} \qquad ( Expression 2 )$$

Expressions 1 and 2 will now be discussed.

Here, d is the film thickness, λ₀ is the wavelength of light, and n1 and n2 are the refractive indices of the core layer and the cladding layer, respectively. When the waveguide parameter V satisfies V<2.405, the waveguide serves as a single-mode waveguide in which, for any wavelength, only the fundamental waveguide mode can be guided and other radiation modes serve as the emission modes. When the difference of refractive index ratio Δ=(n₁−n₂)/2n₁ of the core and the claddings is set to any value, the number of waveguide modes can be reduced by reducing the film thickness, so that the number of emission modes can be increased to increase the light extraction efficiency. When the film thickness is as large as 10 μm or more, the waveguide serves as a multimode waveguide, and the number of waveguide modes increases, causing a reduction in the light extraction efficiency. In the structure of the present invention, the thickness is preferably 10 μm or less at which the wavelength conversion portion reliably functions as a waveguide. However, the film thickness may be greater than or equal to the above thickness.

Assume that the blue light, the green light, and the red light that define display colors correspond to 460 nm, 530 nm, and 630 nm, respectively. As the wavelength increases, the waveguide parameter decreases and the number of waveguide modes decreases accordingly. In other words, the film thickness and the difference of refractive index ratio may be set so that the mode is single mode for green light and red light and multimode for blue light. Thus, the wavelength conversion portion may be structured to serve as a multimode waveguide for blue light and such that, for the wavelength converted light, the radiation modes are dominant to enable efficient light extraction.

FIG. 4 illustrates the boundaries at which the waveguide parameter V is V=2.405 based on the relationship between the difference of refractive index ratio Δ and the film thickness for each of blue light, green light, and red light. When any combination of the difference of refractive index ratio Δ and the film thickness is plotted, the mode for each color is single mode when the boundary for the color is on the right side of the plotted point and multimode when the boundary for the color is on the left side of the plotted point.

For example, when the film thickness is 3 μm and the difference of refractive index ratio Δ is Δ=0.35, the mode is multimode for blue light and single mode for the wavelength converted light (green light and red light). In other words, the structure serves as a waveguide for blue light, and the emission modes are dominant for the wavelength converted light. When the film thickness is 10 μm, the difference of refractive index ratio Δ needs to be Δ=0.03 to form a similar structure, and it is difficult to form the structure in which single mode is set for the wavelength converted light.

When the film thickness is further increased, it becomes impossible to produce the structure in practice. However, even when a complete single mode is not provided, the effect of reducing the waveguide modes can be obtained by bringing the conditions closer to single mode conditions. Therefore, when the difference of refractive index ratio Δ is constant, the light extraction efficiency increases as the film thickness decreases. In a single-mode waveguide, a portion of the guided light (blue light in this example) leaks into the cladding layers as evanescent waves. Therefore, the cladding layers may contain quantum dots that have a wavelength conversion function.

### Modification 1 of Conversion Layer

Display elements 110 to 160 according to second to seventh embodiments will be described with reference to FIGS. 5A to 5F. The second to seventh embodiments correspond to modifications of the first embodiment that differ from the first embodiment in the optical arrangement of the conversion layer including the coupling portion.

### Second Embodiment

The display element 110 according to the second embodiment illustrated in FIG. 5A differs from the first embodiment in that the display element 110 includes a coupling portion 23 that is separated from the light-emitting layer 10 and that has a gap provided between the light-emitting layer 10 and the first conversion portion 26.

### Third Embodiment

The display element 120 according to the third embodiment illustrated in FIG. 5B differs from the first and second embodiments in that the display element 120 includes a coupling portion 23 that is separated from the light-emitting layer 10 with a coupling member 15 provided between the light-emitting layer 10 and the coupling portion 23. The light-shielding portion 10s according to the present embodiment extends to the outer edges of the coupling member 15.

### Fourth Embodiment

The display element 130 according to the fourth embodiment illustrated in FIG. 5C differs from the first to third embodiments in that the display element 130 includes a coupling portion 23 that is separated from the light-emitting layer 10 with a direction-changing member 13 for changing the propagation direction provided between the light-emitting layer 10 and the coupling portion 23. The light-shielding portion 10s of the present embodiment extends to the outer edges of the direction-changing member 13. The direction in which the primary light is emitted from the light-emitting layer 10 of the present embodiment is the same as the second direction D2 parallel to the layer thickness direction of the first conversion layer 20. However, the extraction region in which the secondary light L is extracted from the first extraction portion 24 and the emission region in which the primary light L1 is emitted from the light-emitting layer 10 are shifted from each other so as not to overlap in the x direction to form a non-coaxial structure.

### Fifth Embodiment

The display element 140 according to a fifth embodiment illustrated in FIG. 5D differs from the first to fourth embodiments in that a window 24d with a low wavelength selectivity is provided near a terminal end of the first extraction portion 24 that is opposite to the end at which the coupling portion 20 is provided. The light L1 of the first wavelength does not need to be propagated in the waveguide modes in the direction away from the coupling portion 20 beyond the terminal end of the first light-emitting layer 20, and the component of the light L1 of the first wavelength is substantially absorbed before reaching the position at which the window 24d is provided. Therefore, the window 24d is provided.

### Sixth Embodiment

The display element 150 according to the sixth embodiment illustrated in FIG. 5E differs from the first to fifth embodiments in that a front reflection portion 28p is provided on the first extraction portion 24 in a local region near the coupling portion 22. This arrangement is used to mitigate the situation that, in an upstream region along the propagation path of the first light-emitting layer 20, the component ratio of the light L1 of the first wavelength to the light L2 of the second wavelength is high and the forward leakage of the primary light L1 cannot be fully reduced by the wavelength selectivity of the extraction portion 24.

### Seventh Embodiment

The display element 160 according to the seventh embodiment illustrated in FIG. 5F differs from the first to sixth embodiments in that a light-shielding portion 24s is provided on the first extraction portion 24 at a position near the coupling portion 22. The light-shielding portion 24s corresponds to an extension of the light-shielding portion 10s. The light-shielding portion 24s has an effect similar to that of the front reflection portion 28p according to the sixth embodiment.

### Modification 2 of Conversion Layer

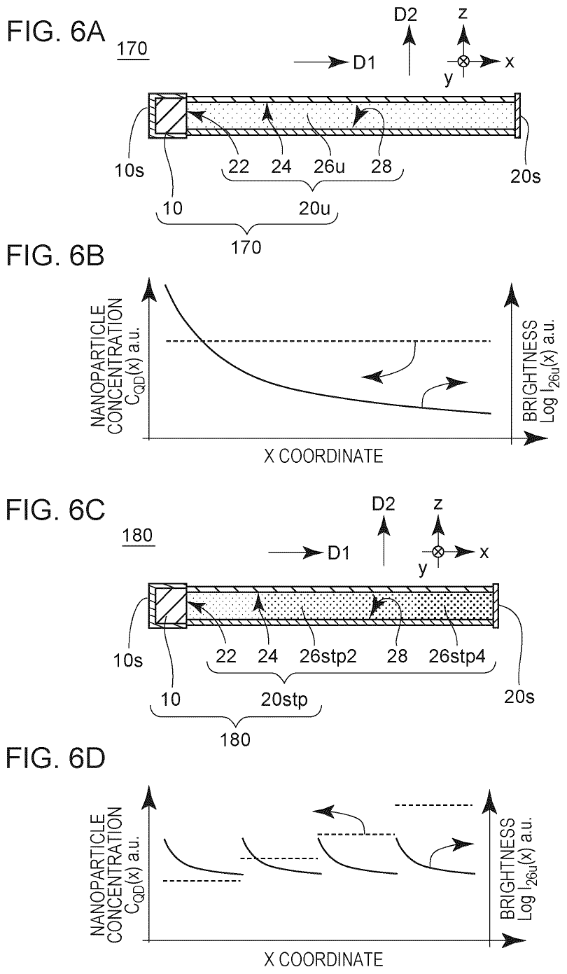

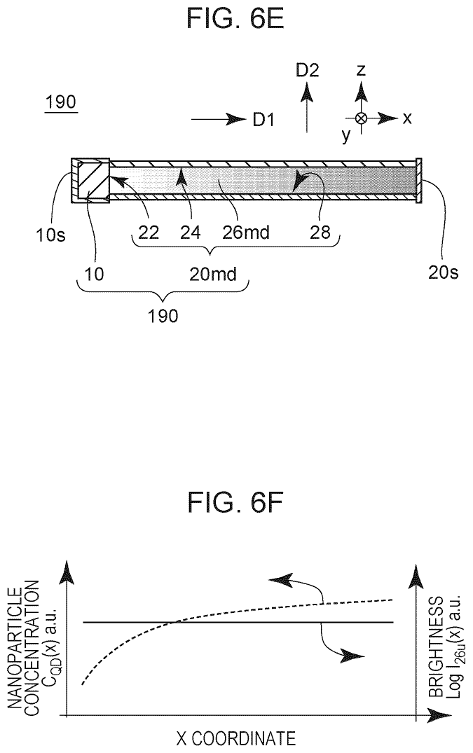

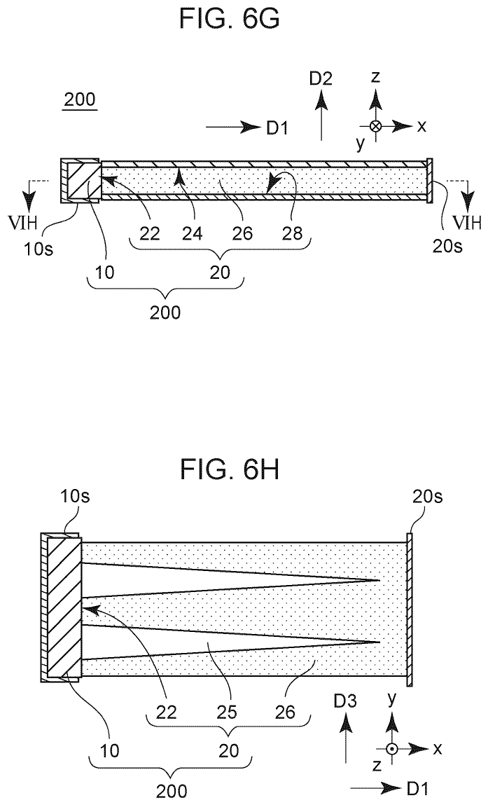

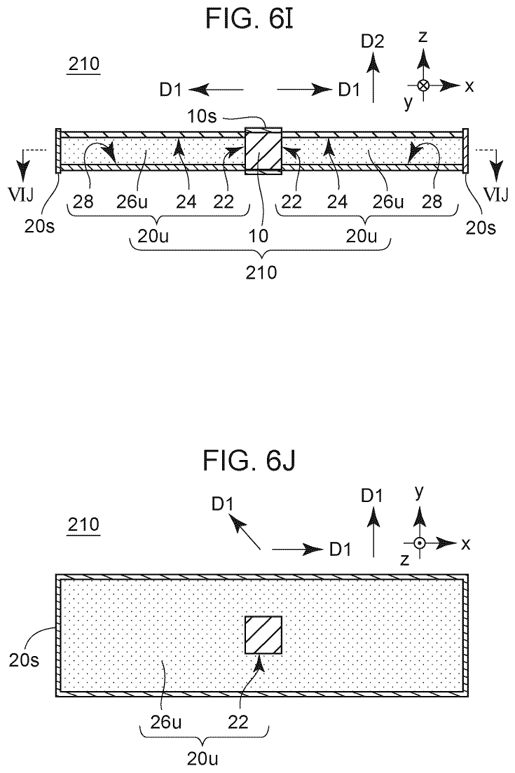

Display elements 170 to 210 according to eighth to twelfth embodiments will be described with reference to FIGS. 6A to 6J. The eighth to twelfth embodiments correspond to modifications of the first embodiment that differ from the first embodiment in that the optical density of the photoresponsive nanoparticles has a specific distribution in the first conversion layer 20.

### Eighth Embodiment

The display element 170 according to the eighth embodiment illustrated in FIG. 6A differs from the first embodiment in that a first conversion layer 20u includes a first conversion portion 26u containing photoresponsive nanoparticles at a constant optical density (dashed line) in the first direction D1, as illustrated in FIG. 6B.

In the first conversion layer 20u, based on the Beer-Lambert law, the amount of the light L2 of the second wavelength emitted from the first conversion portion 26u has a logarithmic distribution in the region from the coupling portion 22 to the end light-shielding portion 20s. To place the centroid of light emission in each pixel at the center of the pixel, the spectral characteristics of other optical elements including the first extraction portion 24 and the first reflection portion 28 may be used to modify the brightness profile illustrated in FIG. 6B.

In FIGS. 6B, 6D, and 6F, the brightness represents the amount of light emitted from the first extraction portion 24 per unit area.

### Ninth Embodiment

The display element 180 according to the ninth embodiment illustrated in FIG. 6C differs from the first and eighth embodiments in that, as illustrated in FIG. 6D, the display element 180 has an optical density distribution (dashed lines) in which the optical density of the photoresponsive nanoparticles increases stepwise with increasing distance from the coupling portion 22 in the first direction D1.

Accordingly, in the display element 180, as illustrated in FIG. 6D, based on the Beer-Lambert law, the distribution of the amount of the light L2 of the second wavelength is smoother than that in the eighth embodiment in the region from the coupling portion 22 to the end light-shielding portion 20s.

### Tenth Embodiment

The display element 190 according to the tenth embodiment illustrated in FIG. 6E differs from the first, eighth, and ninth embodiments in that, as illustrated in FIG. 6F, the display element 190 has an optical density distribution (dashed line) in which the optical density of the photoresponsive nanoparticles continuously increases with increasing distance from the coupling portion 22 in the first direction D1. In other words, the first conversion layer 20 of the present embodiment has a first optical gradient such that the optical density of the photoresponsive nanoparticles 38 increases with increasing distance from the first coupling portion 22 in the layer surface direction of the first conversion layer 20.

FIG. 6E illustrates the structure of a pixel whose display color is green. Although the structure of a pixel whose display color is red is not illustrated, the brightness can be smoothed by using a structure similar to that of the display element 190 whose display color is green. In other words, the second conversion layer 20-2 has a second optical gradient such that the optical density of the photoresponsive nanoparticles 38 increases with increasing distance from the second coupling portion 22 in the layer surface direction of the second conversion layer 20-2.

In the display element 180, as illustrated in FIG. 6D, based on the Beer-Lambert law, the distribution of the amount of the light L2 of the second wavelength is still smoother than that in the ninth embodiment in the region from the coupling portion 22 to the end light-shielding portion 20s.

### Eleventh Embodiment

The display element 200 according to the eleventh embodiment illustrated in FIGS. 6G and 6H differs from the other embodiments in that, as illustrated in FIG. 6H, wedge-shaped inactive regions 25 are provided so that the optical density of the photoresponsive nanoparticles continuously spatially increases with increasing distance from the coupling portion 22.

The wedge-shaped inactive regions 25 may be composed of regions in which only the photoresponsive nanoparticles are excluded from the components contained in the first conversion portion 26.

### Twelfth Embodiment

The display element 210 according to the twelfth embodiment illustrated in FIGS. 61 and 6J differs from the other embodiments in that the light-emitting layer 10 is provided at the center of the first coupling portion 20, as illustrated in FIGS. 61 and 6J. Similarly to the eighth embodiment, the first conversion layer 20 according to the present embodiment contains photoresponsive nanoparticles at a constant optical density in directions away from the coupling portion 22 along the xy plane.

Therefore, the light L2 of the second wavelength (wavelength converted light) has a microscopic brightness distribution along the xy plane in the display element 210. However, since the emission beam distribution in each pixel is a substantially concentric rectangular loop-shaped emission distribution, the centroid of light emission of each of RGB colors coincides with the pixel center.

### Thirteenth Embodiment

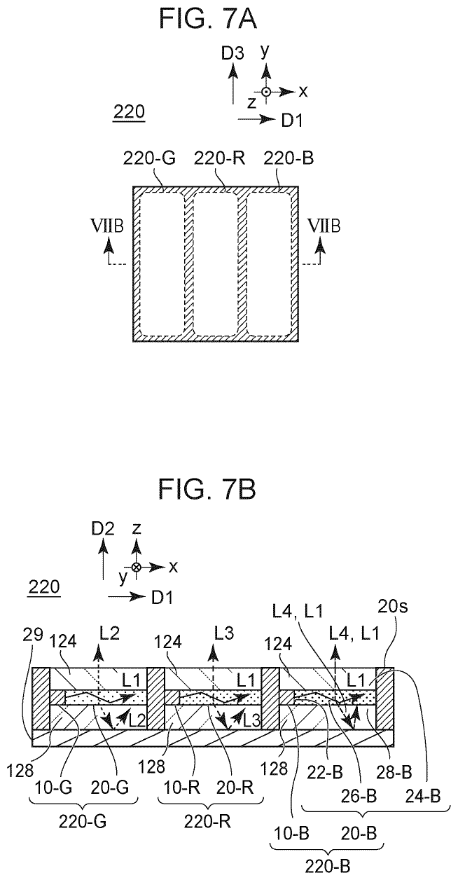

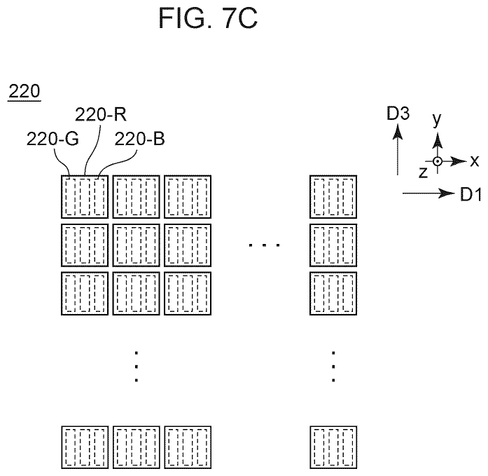

A display element 220 according to a thirteenth embodiment, which is a modification of the display element 100 according to the first embodiment, will be described with reference to FIGS. 7A to 7C. FIG. 7B is a sectional view of the display element 220 illustrated in FIG. 7A taken along plane VIIB-VIIB.

As illustrated in FIGS. 7A and 7C, the display element 220 according to the present embodiment includes a plurality of display elements 220-G, 220-R, and 220-B arranged in a matrix pattern as green, red, and blue subpixels. For simplicity, in the present embodiment, suffixes “-G”, “-R”, and “-B” representing the colors of light emitted from each pixel may be used instead of sub numbers “-1”, “-2”, “-3” in the drawings.

As illustrated in FIG. 7B, the display element 220 includes a black matrix 20s that defines the periphery of the pixel and a first light-emitting layer 10-1, a second light-emitting layer 10-2, and a third light-emitting layer 10-3 disposed in three types of regions surrounded by the black matrix 20s. The display element 220 also includes first to third conversion layers 20-1 to 20-3 that are optically coupled to the first to third light-emitting layers 10-1 to 10-3, respectively, in the respective ones of the three types of regions surrounded by the black matrix 20s. The display element 220 also includes optical members 124 having a refractive index lower than those of the conversion layers 20-1 to 20-3 in front of the first to third conversion layers 20-1 to 20-3 to form extraction portions 24-1 to 24-3, respectively. The display element 220 also includes optical members 128 having a refractive index lower than those of the conversion layers 20-1 to 20-3 behind the first to third conversion layers 20-1 to 20-3 to form reflection portions 28-1 to 28-3, respectively. The black matrix 20s and the optical member 28 are joined to a multilayer dielectric film 29.

When viewed along an axis parallel to the layer thickness direction of the display element 220, the first extraction portion 24-G and the second extraction portion 24-R are arranged next to each other along an xy plane such that the first extraction portion 24-G and the second extraction portion 24-R at least include portions that do not overlap. Similarly, when viewed along an axis parallel to the layer thickness direction of the display element 220, the second extraction portion 24-R and the third extraction portion 24-B are arranged next to each other along the xy plane such that the second extraction portion 24-R and the third extraction portion 24-B at least include portions that do not overlap. In FIG. 7B, the first extraction portion 24-G and the second extraction portion 24-R are omitted for simplicity.

### Fourteenth Embodiment

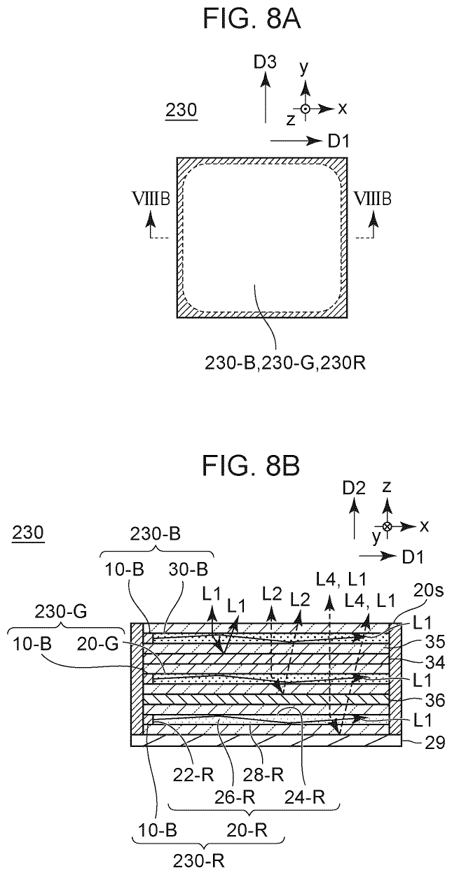

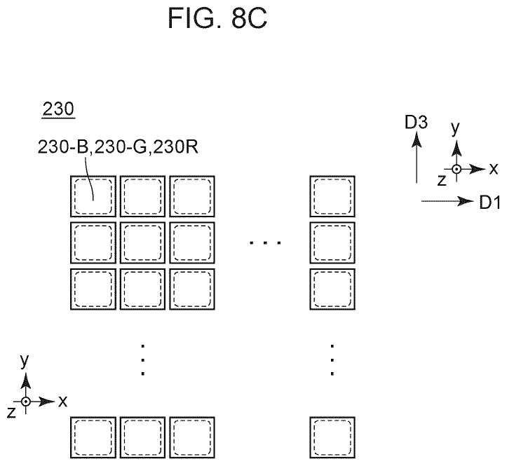

A display element 230 according to a fourteenth embodiment, which is a modification of the display element 230 according to the thirteenth embodiment, will be described with reference to FIGS. 8A to 8C. FIG. 8B is a sectional view of the display element 230 illustrated in FIG. 8A taken along plane VIIIB-VIIIB.

As illustrated in FIGS. 8A and 8C, the display element 230 according to the present embodiment differs from the display element 220 in that the display elements 230-R, 230-G, and 230-B forming the red, green, and blue pixels are stacked in the layer thickness direction of the conversion layer 20-R.

When viewed along an axis parallel to the layer thickness direction of the display element 230, the first extraction portion 24-G and the second extraction portion 24-R are stacked in the z direction such that the first extraction portion 24-G and the second extraction portion 24-R at least include portions that overlap. Similarly, when viewed along an axis parallel to the layer thickness direction of the display element 230, the second extraction portion 24-R and the third extraction portion 24-B are stacked in the z direction such that the second extraction portion 24-R and the third extraction portion 24-B at least include portions that overlap. In FIG. 8B, the first extraction portion 24-G and the second extraction portion 24-R are omitted for simplicity.

As illustrated in FIG. 8B, the display element 230 includes a black matrix 20s that defines the periphery of the pixel and a first light-emitting layer 10-1, a second light-emitting layer 10-2, and a third light-emitting layer 10-3 disposed in one pixel region surrounded by the black matrix 20s. The display element 230 also includes first to third conversion layers 20-1 to 20-3 that are optically coupled to the first to third light-emitting layers 10-1 to 10-3, respectively, in the respective ones of the three types of regions surrounded by the black matrix 20s. The display element 230 also includes optical members 35 having a refractive index lower than those of the conversion layers 20-1 to 20-3 in front of the first to third conversion layers 20-1 to 20-3 to form extraction portions 24-1 to 24-3, respectively. The display element 230 also includes optical members 35 having a refractive index lower than those of the conversion layers 20-1 to 20-3 behind the first to third conversion layers 20-1 to 20-3 to form reflection portions 28-1 to 28-3, respectively. The black matrix 20s and the lowermost optical member 35 are joined to a multilayer dielectric film 29.

As illustrated in FIG. 8B, the display element 230 includes the display elements 230-B, 230-R, and 230-G that constitute subpixels and that are stacked in the light extraction direction in that order from the display surface.

Wavelength-selective optical layers 34 and 36 are disposed between the conversion layers 20-B, 20-G, and 20-R. The optical layer 34, disposed between the conversion layers 20-B and 20-G, is provided as a wavelength-selective layer that reflects blue light and transmits green light and red light, that absorbs blue light, or that has both of these wavelength selection characteristics. The optical layer 36, disposed between the conversion layers 20-G and 20-R, is provided as a wavelength-selective layer that reflects green light and transmits red light, that absorbs green light, or that has both of these wavelength selection characteristics. The wavelength selection characteristics may be referred to also as spectral characteristics.

The optical layer 34 and the optical layer 36 may be low-refractive-index layers having refractive indices lower than that of the optical members 35. When silicon dioxide SiO₂ (refractive index=1.45) is used as a core material, the refractive index of the optical members 35 is preferably 1.10 or more and 1.30 or less, and more preferably 1.10 or more and 1.15 or less.

Assume that the optical layers 34 and 36 are wavelength-selective reflective layers. Among light emitted from the conversion layer 230-B, light emitted forward is directly extracted, and light emitted rearward is reflected by the optical layer 34 and extracted. Among light emitted from the conversion layer 230-G, light emitted forward is extracted through the optical layer 34 and the conversion layer 230-B, and light emitted rearward is reflected by the optical layer 36 and similarly extracted. Among light emitted from the conversion layer 230-R, light emitted forward is extracted through the optical layer 36, the conversion layer 230-G, the optical layer 34, and the conversion layer 230-B, and light emitted rearward is reflected by the reflective layer 20 and similarly extracted.

In the display element 230 including the multilayer subpixels as illustrated in FIG. 8B, the area of the conversion layers is three times as large as that in the display element 220 when the resolution of the display pixels is the same as that in FIG. 7B. Accordingly, even when the absorption of light by the multilayer structure is taken into consideration, an improvement in brightness can be expected. Alternatively, when conversion layers having the same projection area as that in FIG. 8B when viewed in the z direction are stacked, the pixel size is ⅓ of that in the display element 220, and the resolution is increased by a factor of 3.

### EXAMPLES

Display elements according to Examples of the present invention will now be described in detail. However, the present invention is not limited to Examples described below.

### Example 1

### Production of Cladding Layer

A 1-μm-thick film containing 4.5 at % of TiO₂ in SiO₂ was formed on a quartz substrate by co-sputtering of SiO₂ and TiO₂ (substrate A1). The refractive index was measured as 1.477, and the difference of refractive index ratio Δ as 1.5. Similarly, a 100-nm-thick film of Al was formed on a quartz substrate as a reflective film by sputtering, and then a 1-μm-thick optical film containing 4.5 at % of TiO₂ in SiO₂ was formed by co-sputtering of SiO₂ and TiO₂ (substrate A2).

A 1-μm-thick film containing 8.0 at % of TiO₂ in SiO₂ was formed on a quartz substrate by co-sputtering of SiO₂ and TiO₂ (substrate B1). The refractive index was measured as 1.495, and the difference of refractive index ratio Δ as 0.35. Similarly, a 100-nm-thick film of Al was formed on a quartz substrate as a reflective film by sputtering, and then a 1-μm-thick film containing 8.0 at % of TiO₂ in SiO₂ was formed by co-sputtering of SiO₂ and TiO₂ (substrate B2).

### Production of Conversion Layer

Cesium carbonate (10 parts), oleic acid (27 parts), and 1-octadecene (385 parts) were placed in a flask, heated to a liquid temperature of 120° C., and degassed with a vacuum pump for 30 minutes. The liquid was further heated and maintained at 150° C. for 30 minutes in a dry nitrogen gas flow to obtain a cationic raw material solution.

In a separate process, lead bromide (II) (10 parts) and 1-octadecene (494 parts) were placed in a flask, heated to a liquid temperature of 120° C., and degassed with a vacuum pump for one hour. Then, oleic acid (89 parts) and oleylamine (31 parts) were added, and the mixture was further degassed with a vacuum pump for 30 minutes. After that, the liquid temperature was set to 185° C. instead of using a nitrogen flow.

The cationic raw material solution (40 parts) was added, and 5 seconds later the mixture was cooled with ice. Ethyl acetate (2000 parts) was added, and the mixture was subjected to centrifugal separation to remove supernatant fluid. The obtained residue was dispersed into toluene to adjust the solid concentration to 1 weight percent. Thus, liquid in which luminous nanocrystals having the CsPbBr₃ perovskite crystal structure were dispersed was obtained.

The above-described CsPbBr₃-dispersed liquid was subjected to a dry nitrogen gas flow to remove the solvent and processed to prepare an ink composition A containing 1 wt % of CsPbBr₃ nanocrystals, 94 wt % of 3,3,5-trimethylcyclohexyl acrylate (TMCHA), and 5 wt % of 1-hydroxycyclohexyl phenyl ketone (Omnirad 184).

The above-described ink composition was applied to a glass substrate to form a film. The refractive index of the film was calculated from the reflection spectrum as 1.500.

The above-described ink composition A was printed on the optical film on the substrate A2 by using a material printer (DMP-2850 produced by FUJIFILM Dimatix, Inc.) to form a conversion layer extending from an end of the substrate and having a width of 100 μm, a length of 300 μm, and a thickness of 10 μm. After the printing process, the ink composition A was quickly sandwiched between the optical film on the substrate A2 and the optical film on the substrate A1 and cured by UV irradiation. Thus, a display element in which the light L2 of the second wavelength was green light was produced.

A display element in which the conversion layer emits red light was also produced by similar processes in which CsPbBr₃ was changed to CsPb (Br_{0.35}I_{0.65})₃.

### Example 2

Display elements were produced similarly to Example 1 except that the thickness of the conversion layer was changed to 3 μm.

### Example 3

Display elements were produced similarly to Example 1 except that the thickness of the conversion layer was changed to 1.5 μm.

### Example 4

Display elements were produced similarly to Example 1 except that the substrate A1 was changed to the substrate B1 and the substrate A2 to the substrate B2, and that the thickness of the conversion layer was changed to 3 μm.

### Example 5

Display elements were produced similarly to Example 1 except that a conversion layer was printed to extend from an end of the substrate and have a width of 300 μm, a length of 100 μm, and a thickness of 3 μm.

### Example 6

Similarly to Example 1, the CsPbBr₃-dispersed liquid was subjected to a dry nitrogen gas flow to remove the solvent and processed to prepare an ink composition B containing 1 wt % of CsPbBr₃ nanocrystals, 89 wt % of 3,3,5-trimethylcyclohexyl acrylate (TMCHA), 5 wt % of 1-hydroxycyclohexyl phenyl ketone (Omnirad 184), and 5 wt % of titanium oxide.

First, similarly to Example 1, printing was performed to form a conversion layer extending from an end of the substrate and having a width of 80 μm, a length of 300 μm, and a thickness of 10 μm. Then, the ink composition B was printed adjacent to the conversion layer to form a layer having a width of 20 μm, a length of 300 μm, and a thickness of 10 μm, thereby producing a display element. This structure corresponds to FIG. 7B.

### Example 7

Display elements were produced similarly to Example 6 except that the substrate A1 was changed to the substrate B1 and the substrate A2 to the substrate B2, and that the thickness of the conversion layer was changed to 3 μm. This structure corresponds to FIG. 7B.

### Example 8

In this example, subpixels were stacked in the light extraction direction as illustrated in FIGS. 8A to 8C.

First, a substrate including the optical layer 34 formed on a quartz substrate and a substrate including the optical layer 36 formed on a quartz substrate were produced. The optical layer 34 and the optical layer 36 are wavelength selective layers that selectively reflect or transmit light having specific wavelengths. The wavelength selective layers may be formed of dielectric multilayer films. The dielectric that forms the dielectric multilayer films may be an inorganic material, an organic material, or a combination thereof. Examples of the organic material include polyester resins, urethane resins, and acrylic resins. The inorganic material may be a fluoride material or an oxide material. Examples of the fluoride material include AlF₂ (1.36), MgF₂ (1.38), and CaF₂ (1.43). Examples of the oxide material include SiO₂ (1.45), Al₂O₃ (1.64), MgO (1.72), Y₂O₃ (1.88), HfO₂ (2.05), SrTiO₃ (2.44), and TiO₂ (2.49). The numbers in brackets are reference values of refractive indices.

The dielectric multilayer film is composed of a multilayer film in which layers of low-refractive-index and high-refractive-index materials selected from the above-described materials are alternately stacked.

When the thickness d of each layer is set to satisfy d=λ₀/4n, where n is the refractive index of each layer at a center wavelength λ₀ of a reflective band, light components reflected at the boundaries between the layers cancel each other so that the transmittance is reduced and that the reflective band is formed. When the refractive index of the high-refractive-index material is n_{H} and the refractive index of the low-refractive-index material is n_{L}, reflective bands with a width of W=2/π×Sin[(n_{H}−n_{L})/(n_{H}+n_{L})]×λ₀ are formed on both sides of the center wavelength.

The dielectric multilayer film of the optical layer 34 is designed to reflect blue light (460 nm) and transmit light emitted from the conversion layers, that is, green light (530 nm) from the green subpixel and red light (630 nm) from the red subpixel. The dielectric multilayer film of the optical layer 36 is designed to reflect green light (530 nm) from the green subpixel and transmit red light (630 nm) from the red subpixel.

In the example described below, assume that the low-refractive-index material is SiO₂ and the high-refractive-index material is TiO₂. Assuming that alternate stacking of a SiO₂ film and a TiO₂ film is defined as once, a multilayer film obtained by repeating the alternate stacking ten times will be described as an example. The thicknesses of the SiO₂ and TiO₂ films of the optical layer 34 are determined in accordance with the center wavelength of the reflective band for the incident light at the incident angle of 0 degrees. In one example of the optical layer 34, when the center wavelength of the reflective band is 400 nm, the thicknesses of the SiO₂ and TiO₂ films are 69 nm and 40 nm, respectively, and the total film thickness is 1090 nm. In this case, the width of the reflective band is about 133 nm. In one example of the optical layer 36, when the center wavelength of the reflective band is 470 nm, the thicknesses of the SiO₂ and TiO₂ films are 81 nm and 47 nm, respectively, and the total film thickness is 1282 nm. In this case, the width of the reflective band is about 156 nm. The reflective layers can be produced by, for example, sputtering, ion-beam deposition, or pulsed laser deposition (PLD).

Similarly to Example 1, a green subpixel display element including the conversion layer emitting green light was produced by using the substrate on which the optical layer 34 was formed, and a red subpixel display element including the conversion layer emitting red light was produced by using the substrate on which the optical layer 36 was formed. The area of the conversion layers was 300 μm×300 μm. Similarly to Example 1, a blue subpixel display element was produced by forming a resin portion of 300 μm×300 μm containing the light-scattering material by using an ink composition obtained by removing CsPbBr₃ nanocrystals from the ink composition B. The red subpixel display element, the green subpixel display element, and the blue subpixel display element were stacked in that order on an Al reflective film to produce a display element.

### Comparative Example 1

A dielectric multilayer film mirror that transmits blue light and reflects green light and red light was formed on a quartz substrate by ion-beam deposition. The dielectric multilayer film mirror transmits blue light (460 nm) incident at an angle of 0 to 30 degrees and reflects blue light incident at an angle of 30 degrees or more. The dielectric multilayer film mirror reflects green light (530 nm) and red light (630 nm) incident at any angle. Multilayer films made of SiO₂ and TiO₂ were used, and multilayer films having reflective bands with the center wavelengths of 580 nm, 670 nm, and 760 nm were stacked to form a reflective layer. The film thicknesses of SiO₂ and TiO₂ were 100 nm and 58 nm, 116 nm and 67 nm, and 131 nm and 76 nm. The number of repetitions for each band was 5, and the total film thickness of the reflective layer was 2.7 μm.

Similarly to Example 1, the CsPbBr₃-dispersed liquid was subjected to a dry nitrogen gas flow to remove the solvent and processed to prepare an ink composition C containing 10 wt % of CsPbBr₃ nanocrystals, 75 wt % of 3,3,5-trimethylcyclohexyl acrylate (TMCHA), 5 wt % of 1-hydroxycyclohexyl phenyl ketone (Omnirad 184), and 10 wt % of titanium oxide.

The above-described ink composition C was printed on the dielectric multilayer film mirror on the quartz substrate to form a conversion layer having a width of 100 μm, a length of 300 μm, and a thickness of 10 μm, similarly to Example 1, thereby producing a display element. This structure corresponds to FIG. 3B.

### Comparative Example 2

The same ink composition C as that used in Comparative Example 1 was printed on a quartz substrate to form a conversion layer having a width of 100 μm, a length of 300 μm, and a thickness of 10 μm, similarly to Example 1, thereby producing a display element. This structure corresponds to FIG. 3A.

### Comparative Example 3

Similarly to Comparative Example 1, an ink composition D containing 1 wt % of CsPbBr₃ nanocrystals, 84 wt % of 3,3,5-trimethylcyclohexyl acrylate (TMCHA), 5 wt % of 1-hydroxycyclohexyl phenyl ketone (Omnirad 184), and 10 wt % of titanium oxide was prepared.

The same ink composition D as that used in Comparative Example 1 was printed on a quartz substrate to form a conversion layer having a width of 100 μm, a length of 300 μm, and a thickness of 10 μm, similarly to Example 1, thereby producing a display element. This structure corresponds to FIG. 3A.

### Brightness Evaluation

Blue light having a peak light emission wavelength of 460 nm was guided through an optical fiber as excitation light, and the emitted light was focused by a lens and caused to enter the conversion layer from the side. The amount of blue light (intensity×area) was maintained constant. The intensity of blue light per unit area increases as the film thickness decreases. The intensity is greater for Example 5. An integrating sphere was placed directly above the conversion layer, and a multichannel spectrometer C10027-01 (Hamamatsu Photonics) was used to measure the integrated values of the emission spectrum over 530 nm±30 nm for green light and 630 nm±30 nm for red light as brightnesses.

Table 1 shows the brightnesses of green and red.

TABLE 1

| | | | | Subpixel | | | | | | |
|---|---|---|---|---|---|---|---|---|---|---|
| | | | Subpixel | Length | | | | | | |
| | | | Length | Orthogonal | | | | | | |
| | | | in B-Light | to B-Light | | Luminous | Scattering | Film | | |
| | | Lower | Incident | Incident | | Nanocrystal | Material | Thick- | | |
| | | Reflective | Direction | Direction | | Concentration | Concentration | ness | Green | Red |
| | Element Structure | Layer | [μm] | [μm] | Δn | [wt %] | [wt %] | [μm] | Brightness | Brightness |
| Example 1 | Wavequide | Al | 100 | 300 | 1.5 | 1.0 | 0 | 10 | 69 | 70 |
| Example 2 | Waveguide | Al | 100 | 300 | 1.5 | 1.0 | 0 | 3 | 70 | 71 |
| Example 3 | Waveguide | Al | 100 | 300 | 1.5 | 1.0 | 0 | 1.5 | 72 | 73 |
| Example 4 | Wavequide | Al | 100 | 300 | 0.35 | 1.0 | 0 | 3 | 78 | 79 |
| Example 5 | Waveguide | Al | 300 | 100 | 1.5 | 1.0 | 0 | 3 | 68 | 70 |
| Example 6 | Waveguide + End | Al | 100 | 300 | 1.5 | 1.0 | 0, | 10 | 76 | 77 |
| | Scattering Portion | | | | | | (End 5 wt %) | | | |
| Example 7 | Waveguide + End | Al | 100 | 300 | 0.35 | 1.0 | 0, | 3 | 81 | 81 |
| | Scattering Portion | | | | | | (End 5 wt %) | | | |
| Example 8 | Waveguide + | Wavelength | 300 | 300 | 0.35 | 1.0 | | 3 | 104 | 122 |
| | Multilayer Structure | Selective | | | | | | | | |
| | | Mirror | | | | | | | | |
| Comparative | Scattering Material | Wavelength | (100) | (300) | — | 10.0 | 10 | 10 | 59 | 63 |
| Example 1 | | Selective | | | | | | | | |
| | | Mirror | | | | | | | | |
| Comparative | Scattering Material | None | (100) | (300) | — | 10.0 | 10 | 10 | 33 | 35 |
| Example 2 | | | | | | | | | | |
| Comparative | Scattering Material | Wavelength | (100) | (300) | — | 1.0 | 10 | 10 | 40 | 43 |
| Example 3 | | Selective | | | | | | | | |
| | | Mirror | | | | | | | | |

When the difference of refractive index ratio Δ of the waveguide was Δ=1.5, the brightnesses of green and red increased as the film thickness decreased (Examples 1-3). This is probably because the waveguide modes decreased.

When the film thickness of the waveguide was constant at 3 μm, the brightnesses of green and red increased as the difference of refractive index ratio Δ decreased (Examples 2 and 4). This is probably because the waveguide modes decreased.

The brightnesses were substantially constant irrespective of whether the blue light was incident in the long-side direction or the short-side direction (Examples 2 and 5).

When a scattering portion was provided at the end, the brightnesses of green and red increased. This is probably because light in the waveguide modes was scattered at the light scattering portion and extracted as light in the emission modes (Examples 6 and 7).

When the multilayer structure was adopted, the brightnesses of green and red increased. This is because the area of the conversion layers was increased by a factor of 3 (Example 8).

In both Example 1 and Comparative Example 1, the film thickness was 10 μm, and a reflective layer was provided on the lower surface. In Comparative Example 1, although the concentration of the luminous nanocrystals was 10 wt %, the brightnesses of green and red were relatively small. This means that Example 1 had a higher light extraction efficiency. When the concentration of luminous nanocrystals was set to 1 wt % as in Example 1, the brightnesses of green and red further dropped (Comparative Example 3). Also when no reflective layer was provided on the lower surface, the brightnesses of green and red dropped (Comparative Example 2).

According to the display element of the present invention, a display element and a display device with which the macroscopic light utilization efficiency of the wavelength conversion layers and the color purity are both increased can be provided.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

1. A display element comprising:
a light-emitting-layer array including a plurality of light-emitting layers that are arranged in two dimensions and that emit light of a first wavelength; and
a conversion-layer array including a plurality of first conversion layers including a first coupling portion, a first extraction portion, and a first reflection portion, the first coupling portion being optically coupled to a portion of the plurality of light-emitting layers, the first extraction portion and the first reflection portion facing each other to alternately reflect the light of the first wavelength received through the first coupling portion and guide the light of the first wavelength in a direction away from the first coupling portion, the plurality of first conversion layers emitting, through the first extraction portion, light of a second wavelength obtained as a result of wavelength conversion of the light of the first wavelength.

2. The display element according to claim 1, wherein the plurality of first conversion layers contains first photoresponsive nanoparticles that convert the light of the first wavelength into the light of the second wavelength.

3. The display element according to claim 1, wherein the first extraction portion has a spectral reflectance that is higher for the light of the first wavelength than for the light of the second wavelength.

4. The display element according to claim 1, wherein the first extraction portion has a spectral transmittance that is higher for the light of the second wavelength than for the light of the first wavelength.

5. The display element according to claim 1, wherein the second wavelength is longer than the first wavelength.

6. The display element according to claim 1, wherein the first reflection portion has a higher spectral reflectance for the light of the second wavelength than the first extraction portion.

7. The display element according to claim 2, wherein the first conversion layers have a first optical gradient such that an optical density of the photoresponsive nanoparticles increases with increasing distance from the first coupling portion in the layer surface direction.

8. The display element according to claim 1, wherein the conversion-layer array further includes a plurality of second conversion layers including a plurality of second coupling portions, a second extraction portion, and a second reflection portion, the plurality of second coupling portions being optically coupled to the plurality of light-emitting layers in regions other than regions in which the light-emitting-layer array is optically coupled to the plurality of first conversion layers, the second extraction portion and the second reflection portion facing each other to alternately reflect the light of the first wavelength received through the plurality of second coupling portions and guide the light of the first wavelength in a direction away from the second coupling portions, the plurality of second conversion layers emitting, through the second extraction portion, light of a third wavelength obtained as a result of wavelength conversion of the light of the first wavelength.

9. The display element according to claim 8, wherein the plurality of second conversion layers contains second photoresponsive nanoparticles that convert the light of the first wavelength into the light of the third wavelength.

10. The display element according to claim 8, wherein the second extraction portion has a spectral reflectance that is higher for the light of the first wavelength than for the light of the third wavelength.

11. The display element according to claim 8, wherein the second extraction portion has a spectral transmittance that is higher for the light of the third wavelength than for the light of the first wavelength.

12. The display element according to claim 8, wherein the third wavelength is longer than the first wavelength and the second wavelength.

13. The display element according to claim 8, wherein the second reflection portion has a higher spectral reflectance for the light of the third wavelength than the second extraction portion.

14. The display element according to claim 9, wherein the second conversion layers have a second optical gradient such that an optical density of the photoresponsive nanoparticles increases with increasing distance from the second coupling portions in the layer surface direction.

15. The display element according to claim 1, wherein the conversion-layer array further includes a plurality of third conversion layers including third coupling portions, a third extraction portion, and a third reflection portion, the third coupling portions being optically coupled to the plurality of light-emitting layers in regions other than regions in which the light-emitting-layer array is optically coupled to the plurality of first conversion layers or the plurality of second conversion layers, the third extraction portion and the third reflection portion facing each other to alternately reflect the light of the first wavelength received through the third coupling portions and guide the light of the first wavelength in a direction away from the third coupling portions, the plurality of third conversion layers emitting, through the third extraction portion, at least one of the light of the first wavelength and light of a fourth wavelength obtained as a result of wavelength conversion of the light of the first wavelength.

16. The display element according to claim 15, wherein the plurality of third conversion layers contains third photoresponsive nanoparticles that convert the light of the first wavelength into the light of the fourth wavelength that is closer to the first wavelength than the second wavelength and the third wavelength.

17. The display element according to claim 15, wherein the third extraction portion has a spectral reflectance that is higher for the light of the first wavelength than for the light of the fourth wavelength.

18. The display element according to claim 15, wherein the third extraction portion has a spectral transmittance that is higher for the light of the fourth wavelength than for the light of the first wavelength.

19. The display element according to claim 15, wherein the fourth wavelength is longer than the first wavelength.

20. The display element according to claim 15, wherein the third reflection portion has a higher spectral reflectance for the light of the fourth wavelength than the third extraction portion.

21. The display element according to claim 15, wherein the plurality of third conversion layers changes a propagation direction in an optical propagation path from each of the third coupling portions to the third extraction portion but does not perform wavelength conversion of the light of the first wavelength.

22. The display element according to claim 1, wherein, when viewed along an axis parallel to the layer thickness direction, the first coupling portion does not overlap the first extraction portion.

23. The display element according to claim 8, wherein, when viewed along an axis parallel to the layer thickness direction, the first extraction portion and the second extraction portion include parts that do not overlap.

24. The display element according to claim 8, wherein, when viewed along an axis parallel to the layer thickness direction, the first extraction portion and the second extraction portion include parts that overlap.
